(19) United States
(12) Patent Application Publication
(10) Pub. No.: US 2015/0068580 A1
(43) Pub. Date: Mar. 12, 2015

(54) PHOTOVOLTAIC THIN-FILM SOLAR MODULES AND METHOD FOR MANUFACTURING SUCH THIN-FILM SOLAR MODULES

(71) Applicant: ROBERT BOSCH GMBH, Stuttgart (DE)

(72) Inventor: Volker Probst, Berlin (DE)

(73) Assignee: Robert Bosch GmbH, Stuttgart (DE)

(21) Appl. No.: 14/391,646

(22) PCT Filed: Mar. 28, 2013
(86) PCT No.: PCT/EP2013/056767

§ 371 Date: Oct. 9, 2014

(30) Foreign Application Priority Data
Apr. 12, 2012 (DE) 10 2012 205 978.4

(51) Int. Cl. H01L 31/0224; H01L 31/18; H01L 31/05; H01L 31/032; H01L 31/0475

(52) U.S. Cl. CPC H01L 31/022441; H01L 31/022483; H01L 31/0323; H01L 31/0327; H01L 31/0475; H01L 31/0508; H01L 31/1828
USPC 136/244; 438/95

(57) ABSTRACT

A photovoltaic thin-film solar module includes in the following sequence: a substrate layer; a back electrode layer directly adjoining the substrate layer; a conductive barrier layer directly adjoining at least one of the back electrode layer and the substrate layer; an ohmic contact layer directly adjoining the barrier layer; one of a chalcopyrite or kesterite semiconductor absorber layer directly adjoining the contact layer; a first buffer layer directly adjoining the semiconductor absorber layer and containing one of Zn(S,OH) or In₂S₃; a second buffer layer directly adjoining one of the semiconductor absorber layer or the first buffer layer; and a transparent front electrode layer directly adjoining at least one of the semiconductor absorber layer, the first buffer layer, and the second buffer layer, the transparent front electrode layer containing n-doped zinc oxide.

### BACKGROUND OF THE INVENTION

1. Field of the Invention

The present invention relates to photovoltaic thin-film solar modules and a method for manufacturing such thin-film solar modules.

2. Description of the Related Art

Photovoltaic solar modules have been known and also commercially available for quite some time. Suitable solar modules include, on the one hand, crystalline, amorphous silicon solar modules, and on the other hand, so-called thin-film solar modules. These types of thin-film solar modules are based, for example, on the use of a so-called chalcopyrite semiconductor absorber layer, such as a Cu(In,Ga) (Se,S) system, and represent a complex multilayer system. In these thin-film solar modules, a molybdenum back electrode layer usually rests on a glass substrate. In one method variant, the molybdenum back electrode layer is provided with a precursor thin metal layer containing copper, indium, and optionally gallium, and is subsequently converted into a so-called CIS or CIGS system in the presence of hydrogen sulfide and/or hydrogen selenide at elevated temperatures. In another method variant, elemental selenium vapor and sulfur vapor may be used instead of hydrogen selenide and hydrogen sulfide. Consequently, the manufacture of such thin-film solar modules is a multistep process in which, due to numerous interactions, each method stage must be carefully coordinated with subsequent method stages. In addition, special care is necessary in the selection and purity of the materials to be used in each layer. Due to plant engineering constraints, it is often extremely difficult or impossible to manufacture thin-film solar modules on a large scale having a module format with a size greater than 1.2 m×0.5 m. In addition, for the temperatures and reaction conditions to be used in the individual manufacturing stages, it has not been possible thus far to exclude contamination or interdiffusion of components, dopants, or impurities of individual layers of the multilayer system. The efficiency of a thin-film solar cell may even be influenced by the selection and the type of production of the back electrode layer. For example, the back electrode layer must have a high transverse conductivity in order to ensure a low-loss series connection. In addition, substances migrating from the substrate and/or the semiconductor absorber layer should have no influence on the quality and function of the back electrode layer or the semiconductor absorber layer. Furthermore, the material of the back electrode layer must be well-adapted to the thermal expansion characteristic of the substrate and the layers situated thereabove in order to avoid microcracks. Lastly, the adhesion to the substrate surface should also meet all common usage requirements. Although it is possible to achieve good efficiencies by using particularly pure back electrode material, this is generally accompanied by unreasonably high manufacturing costs. In addition, the above-mentioned phenomena of migration and in particular diffusion under the customary manufacturing conditions quite often result in significant contamination of the back electrode material. For example, a dopant which is inserted into the semiconductor absorber layer may diffuse into the back electrode due to the above-mentioned diffusion, thus being depleted in the semiconductor absorber layer. Much lower efficiencies of the finished solar module are the consequence. Even when attention is paid to optimizing all methods and materials, one is always greatly limited in the ultimate design of the thin-film solar modules provided for sale.

According to Published German patent document DE 44 42 824 C1, the aim is to obtain a solar cell which includes an absorber layer having a good morphological design and good efficiencies by doping the chalcopyrite semiconductor absorber layer with an element from the group composed of sodium, potassium, and lithium in a dose of 10¹⁴ to 10¹⁶ atoms/cm², and at the same time providing a diffusion blocking layer between the substrate and the semiconductor absorber layer. Alternatively, it is provided to use an alkali-free substrate if a diffusion blocking layer is to be dispensed with.

Blosch et al. (Thin Solid Films 2011) propose, when a polyimide substrate film is used, use of a layer system composed of titanium, titanium nitride, and molybdenum in order to obtain good adhesion properties and a satisfactory thermal property profile. For the use of flexible thin-film solar cells, Blosch et al. (IEEE, 2011, Vol. 1, No. 2, pages 194 through 199) further propose the use of a stainless steel substrate foil to which a thin titanium layer is initially applied for improving the adhesion. Satisfactory results have been obtained with such CIGS thin-film solar cells which are equipped with a titanium/molybdenum/molybdenum triple ply. Improved thin-film solar cells are also the aim of the technical teaching of published international patent application document WO 2011/123869 A2. The solar cell provided therein includes a sodium glass substrate, a molybdenum back electrode layer, a CIGS layer, a buffer layer, a layer made of intrinsic zinc oxide, and a layer made of zinc oxide doped with aluminum. A first separating trench extends over the molybdenum layer, the CIGS layer, and the powder layer, and a second separating trench begins above the molybdenum layer. An insulating material is deposited in or on the first separating trench, and a front electrode layer is to be deposited obliquely on the solar cell, including the first separating trench. The aim is to obtain thin-film solar cells having an improved light yield. The aim of US 2004/014419 A1 is to provide a thin-film solar cell having a molybdenum back electrode layer with improved efficiency. This is to be achieved by providing a glass substrate with a back electrode layer made of molybdenum, the thickness of which should not exceed 500 nm.

The suitability of various metals such as tungsten, molybdenum, chromium, tantalum, niobium, vanadium, titanium, and manganese as appropriate back electrode materials for thin-film solar cells is described in Orgassa et al. (Thin Solid Films, 2003, Vol. 431-432, pages 1987 through 1993).

It would therefore be desirable to be able to rely on a method for manufacturing photovoltaic thin-film solar modules which does not have the disadvantages of the related art, and which in particular manages with fewer process steps and at the same time is not subject to restrictions, such as with regard to module formats, as is known from the methods of the related art. Moreover, the object underlying the present invention is to make thin-film solar modules available which have a larger filling factor and a higher efficiency and which are less sensitive to the conditions of the manufacturing process and which still allow a wide variety of designs with respect to length, width, and shape, for example.

Accordingly, a photovoltaic thin-film solar module (also referred to as the first embodiment of the thin-film solar module according to the present invention) has been found which includes, in particular in the following sequence,

at least one substrate layer, in particular a glass plate,
at least one back electrode layer, in particular directly adjoining the substrate layer, in particular containing or composed essentially of molybdenum,
at least one conductive barrier layer, in particular a bidirectional barrier layer, in particular directly adjoining the back electrode layer and/or the substrate layer,
at least one contact layer, in particular an ohmic contact layer, in particular directly adjoining the barrier layer, in particular containing or composed essentially of molybdenum and/or molybdenum selenide and/or molybdenum sulfoselenide,
at least one semiconductor absorber layer, in particular a chalcopyrite or kesterite semiconductor absorber layer, in particular directly adjoining the contact layer,
optionally at least one first buffer layer, in particular directly adjoining the semiconductor absorber layer, containing or formed essentially from CdS or a CdS-free layer, in particular containing or composed essentially of Zn(S,OH) or In₂S₃, and/or
optionally at least one second buffer layer, in particular directly adjoining the semiconductor absorber layer or the first buffer layer, containing and formed essentially from intrinsic zinc oxide and/or high-resistance zinc oxide, and
at least one transparent front electrode layer, in particular directly adjoining the semiconductor absorber layer, the first buffer layer, and/or the second buffer layer, in particular containing or composed essentially of n-doped zinc oxide, characterized by
spaced-apart first structuring separating trenches which are filled with at least one insulator material and which separate adjacent solar cells from one another up to the substrate layer,
spaced-apart second structuring separating trenches which are filled or provided with at least one conductive material and which extend to the contact layer or to the back electrode layer or to the barrier layer, in particular to the barrier layer, and which in each case are situated adjacent to a filled first structuring separating trench,
spaced-apart third structuring separating trenches which extend to the contact layer or to the back electrode layer or to the barrier layer, in particular to the barrier layer, and which in each case are situated adjacent to a second structuring separating trench, on the other side of the first structuring separating trench which adjoins the second structuring separating trench, and
at least one conductive bridge from second structuring separating trenches which are filled with the conductive material or provided with such a material, over adjacent first structuring separating trenches which are filled with the insulator material, to the front electrode layer of the solar cell which is adjacent thereto, so that adjacent solar cells are electrically connected in series.

Moreover, the object underlying the present invention is achieved by a photovoltaic thin-film solar module (also referred to as the second embodiment of a thin-film solar module according to the present invention), which includes, in particular in the following sequence,

at least one substrate layer, in particular a glass plate,
at least one back electrode layer, in particular directly adjoining the substrate layer, in particular containing or made of molybdenum,
at least one conductive barrier layer, in particular a bidirectional barrier layer, in particular directly adjoining the back electrode layer,
at least one contact layer, in particular an ohmic contact layer, in particular directly adjoining the barrier layer, in particular containing or made of molybdenum and/or molybdenum selenide and/or molybdenum sulfoselenide,
at least one semiconductor absorber layer, in particular a chalcopyrite or kesterite semiconductor absorber layer, in particular directly adjoining the contact layer,
optionally at least one first buffer layer, in particular directly adjoining the semiconductor absorber layer, containing or formed essentially from CdS or a CdS-free layer, in particular containing or composed essentially of Zn(S,OH) or In₂S₃, and/or
optionally at least one second buffer layer, in particular directly adjoining the semiconductor absorber layer or the first buffer layer, containing and formed essentially from intrinsic zinc oxide and/or high-resistance zinc oxide, and at least one transparent front electrode layer, in particular directly adjoining the semiconductor absorber layer, the first buffer layer and/or the second buffer layer, in particular containing or formed essentially from n-doped zinc oxide, characterized by
spaced-apart first structuring separating trenches which are filled with at least one insulator material and which separate adjacent solar cells from one another up to the substrate layer,
spaced-apart fourth structuring separating trenches which extend to the contact layer or to the back electrode layer or to the barrier layer, in particular to the barrier layer, and which in each case are situated adjacent to a filled first structuring separating trench, and which include a first volume area which extends from the barrier layer to the front electrode layer along the separating trench wall adjacent to the first structuring separating trench and which is filled or provided with at least one conductive material, and a second volume area, adjacent thereto, which extends from the contact layer or to the back electrode layer or to the barrier layer, in particular to the barrier layer, up to the front electrode layer, and
at least one conductive bridge from the first volume areas of the second structuring separating trenches which are filled with a conductive material or provided with such a material, over adjacent first structuring separating trenches which are filled with an insulator material, to the front electrode layer of the solar cell which is adjacent thereto, so that adjacent solar cells are electrically connected in series.

In these first and second embodiments of photovoltaic thin-film solar modules according to the present invention, in a first specific embodiment, initially a first conductive barrier layer, thereupon the back electrode layer, thereupon the contact layer, thereupon the semiconductor absorber layer, thereupon optionally the first or second buffer layer, and thereupon the front electrode layer, may be present on the substrate layer. In these first and second embodiments, in addition in a second specific embodiment, initially a first conductive barrier layer, thereupon the back electrode layer, thereupon the second conductive barrier layer, thereupon the contact layer, thereupon the semiconductor absorber layer, thereupon optionally the first or second buffer layer, and thereupon the front electrode layer, may be present on the substrate layer. Furthermore, in the first and second embodiments of thin-film solar modules according to the present invention, in a third specific embodiment which is preferred, initially the back electrode layer, thereupon the conductive barrier layer, thereupon the contact layer, thereupon the semiconductor absorber layer, thereupon optionally the first or second buffer layer, and thereupon the front electrode layer, may be present on the substrate layer.

In one specific embodiment it may be provided that the semiconductor absorber layer represents or includes a quaternary IB-IIIA-VIA chalcopyrite layer, in particular a Cu(In,Ga)Se₂ layer, a pentenary IB-IIIA-VIA chalcopyrite layer, in particular a Cu(In,Ga)(Se₁₋ₓ,Sₓ)₂-layer, or a kesterite layer, in particular a Cu₂ZnSn(Seₓ,S₁₋ₓ)₄-layer, such as a Cu₂ZnSn(Se)₄-layer or a Cu₂ZnSn(S)₄-layer, where x assumes any arbitrary value from 0 to 1.

The substrate preferably represents a plate or film. The substrate may be, for example, a glass substrate such as a glass plate, a flexible or nonflexible plastic layer, such as plastic films, or a metal plate, such as stainless steel layers or foils in particular, having a width greater than 0.5 m, in particular greater than 2.0 m, and a length greater than 1.2 m, in particular greater than 3.0 m. For example, it is even possible to use substrate formats, in particular glass substrate formats, having a width of 3.2 m and a length of 6 m, from which, for example, 16 thin-film solar modules in a 1.6 m×0.7 m module format may be obtained.

In one particularly suitable embodiment, it is provided that the back electrode contains or is formed essentially from V, Mn, Cr, Mo, Ti, Co, Zr, Ta, Nb, and/or W, and/or contains or is formed essentially from an alloy containing V, Mn, Cr, Mo, Ti, Co, Fe, Ni, Al, Zr, Ta, Nb, and/or W. Within the meaning of the present invention, the back electrode may also be referred to as a bulk back electrode, and the system made up of the bulk back electrode or back electrode, barrier layer, and contact layer may be referred to as a multilayer back electrode.

It may also be provided that the barrier layer represents a barrier for in particular diffusing or diffusible components, in particular dopants, which migrate out of and/or through the back electrode layer, and/or for in particular diffusing or diffusible components, in particular dopants, which migrate out of and/or through the contact layer, in particular a bidirectional barrier layer. In the latter case, the barrier layer prevents the depletion from the semiconductor layer of dopant, such as sodium, which forms this layer, as the result of which an unimpaired efficiency may be maintained.

The barrier layer is advantageously a barrier for alkali ions, in particular sodium ions or compounds containing alkali ions, selenium or selenium compounds, sulfur or sulfur compounds, and/or metals, in particular Cu, In, Ga, Fe, Ni, Ti, Zr, Hf, V, Nb, Ta, Al, and/or W.

The barrier layer is preferably a bidirectional barrier layer, and prevents contamination of the semiconductor absorber layer with components from the substrate layer and/or the back electrode layer, as well as contamination of the back electrode layer with components of the semiconductor layer, such as Cu, In, and Ga. In the latter case, the barrier layer prevents the depletion from the semiconductor layer of a metal which forms this layer, as the result of which an unimpaired efficiency may be maintained.

In one particularly advantageous embodiment, the barrier layer of the back electrode according to the present invention has barrier properties, in particular bidirectional barrier properties, with respect to dopants, in particular with respect to dopants for the semiconductor absorber layer and/or from the semiconductor absorber layer, with respect to chalcogens such as selenium and/or sulfur as well as chalcogen compounds, with respect to the metallic components of the semiconductor absorber layer, such as Cu, In, Ga, Sn, and/or Zn, with respect to impurities such as iron and/or nickel from the bulk back electrode layer, and/or with respect to components and/or impurities from the substrate. The bidirectional barrier properties with respect to dopants from the substrate should on the one hand prevent enrichment with alkali ions, diffusing from a glass substrate, for example, at the interface of the back electrode or contact layer with respect to the semiconductor absorber layer. Such enrichment is known as one reason for semiconductor layer delamination. The conductive barrier layer is thus intended to help avoid adhesion problems. On the other hand, the barrier property for dopants which are diffusible or diffusing from the semiconductor absorber should prevent dopant thus being lost at the bulk back electrode and thus depleting the semiconductor absorber of dopant, which would greatly reduce the efficiency of the solar cell or the solar module. It is known, for example, that molybdenum back electrodes are able to absorb significant quantities of sodium dopant. The bidirectional conductive barrier layer should thus allow the requirements to be met for a targeted dosing of dopant into the semiconductor absorber layer, in order to be able to achieve reproducibly high efficiencies of the solar cells and modules.

Therefore, the barrier property with respect to chalcogens should prevent the chalcogens from reaching the back electrode and forming metal chalcogenide compounds there. It is known that these chalcogenide compounds, such as MoSe, contribute to a significant increase in volume of the layer of the back electrode near the surface, which in turn results in unevennesses in the layer structure and impaired adhesion. Impurities such as Fe and Ni in the bulk back electrode material represent so-called deep imperfections for chalcopyrite semiconductors, for example (semiconductor poisons), and therefore must be kept away from the semiconductor absorber layer via the barrier layer.

In one advantageous embodiment, the barrier layer typically has an average thickness of at least 10 nm, in particular at least 30 nm, and preferably 250 nm or 150 nm maximum.

Due to the presence of a barrier layer it is possible, for example, to significantly reduce the degree of purity of the back electrode material. For example, the back electrode layer may have impurities of at least one element selected from the group composed of Fe, Ni, Al, Cr, Ti, Zr, Hf, V, Nb, Ta, W, and/or Na and/or compounds of the mentioned elements without adversely affecting the efficiency of the thin-film solar cell or module which includes the back electrode according to the present invention.

Barrier layers are particularly preferred which contain or are composed essentially of at least one metal nitride, in particular TiN, MoN, TaN, ZrN, and/or WN, at least one metal silicon nitride, at least one metal carbide, at least one metal boride, and/or at least one metal silicon nitride, in particular TiSiN, TaSiN, and/or WSiN. In particular, barrier layers which provide a light-reflecting surface, such as TiN, are used. In this way, light which has passed through the semiconductor absorber layer may be deflected once again by same in order to increase the efficiency.

Metal nitrides of this type, such as TiN, are preferably used as barrier materials within the meaning of the present invention, in which the metal is deposited stoichiometrically or hyperstoichiometrically with respect to nitrogen, i.e., with an excess of nitrogen. In another specific embodiment, it is provided that oxygen is added in this method stage, in particular in small quantities, prior to, during, and/or after the deposition of the barrier layer, in particular a metal nitride or metal silicon nitride barrier layer. The aim is thus to improve the barrier properties without at the same time significantly reducing the conductivity of the barrier. The aim of adding oxygen in conjunction with depositing the barrier layer is to block the grain boundaries of the thin-film barrier, which quite often is polycrystalline, with oxygen or oxygen compounds.

Another advantage of using a barrier layer as a component of a multilayer back electrode system (composed of the back electrode layer, barrier layer, and contact layer) when used in thin-film solar modules according to the present invention is also that the thickness of the semiconductor absorber layer, the chalcopyrite or kesterite layer, for example, may be markedly reduced compared to a conventional system. Due to the presence of the barrier layer, in particular when in the form of metal nitrides such as titanium nitride or containing such metal nitrides or titanium nitrides, the sunlight passing through the semiconductor absorber layer is reflected very effectively, so that a very good quantum yield may be achieved in the course of the double passage through the semiconductor absorber layer. Due to the presence of the mentioned barrier layer in the back electrode according to the present invention or in thin-film solar cells or modules containing this back electrode, the average thickness of the semiconductor absorber layer may be reduced, for example, to values in the range of 0.4 μm to 1.5 μm, for example to values in the range of 0.5 μm to 1.2 μm.

The barrier layer is preferably situated between the back electrode layer and the contact layer. Alternatively or additionally, at least one barrier layer, as described above, may be applied between the substrate layer and the back electrode layer. In such a case, the back electrode layer does not directly adjoin the substrate layer.

In another embodiment it is provided that the contact layer contains or is formed essentially from Mo, W, Ta, Nb, Zr, and/or Co, in particular Mo and/or W, and/or at least one metal chalcogenide, and/or includes at least one first ply, adjacent to the barrier layer, which contains or is composed essentially of Mo, W, Ta, Nb, Zr, and/or Co, in particular Mo and/or W, and at least one second ply, not adjacent to the barrier layer, which contains or is composed essentially of at least one metal chalcogenide. The contact layer preferably directly adjoins the barrier layer on the side facing the substrate and/or directly adjoins the semiconductor absorber layer on the side facing the front electrode. The contact layer suitably contains at least one metal chalcogenide.

The metal of the metal chalcogenide of the contact layer or of the second ply of the contact layer is preferably selected from molybdenum, tungsten, tantalum, zirconium, cobalt, and/or niobium, and the chalcogen of the metal chalcogenide is preferably selected from selenium and/or sulfur, the metal chalcogenide in particular representing MSe₂, MS₂, and/or M(Se₁₋ₓ,Sₓ)₂, where M is Mo, W, Ta, Zr, Co, or Nb, and x assumes any arbitrary value from 0 to 1, for example, MoSe₂, WSe₂, TaSe₂, NbSe₂, Mo (Se₁₋ₓ, Sₓ)₂, W (Se₁₋ₓ, Sₓ)₂, Ta (Se₁₋ₓ, Sₓ)₂, and/or Nb (Se₁₋ₓ, Sₓ)₂.

Such specific embodiments have also proven to be advantageous in which the metal of the first ply and the metal of the second ply of the contact layer are the same, and/or in which the metal of the first ply and/or the metal of the second ply of the contact layer are the same as the metal of the back electrode layer, and/or in which the metal of the contact layer is the same as the metal of the back electrode layer.

In addition, the contact layer usually has an average thickness of at least 5 nm and preferably not greater than 150 nm, particularly preferably not greater than 50 nm.

Thin-film solar modules according to the present invention having even further increased efficiency are often obtained in that the semiconductor absorber layer contains at least one dopant, in particular at least one element selected from the group composed of sodium, potassium, and lithium and/or at least one compound of these elements, preferably with oxygen, selenium, sulfur, boron, and/or halogens such as iodine or fluorine, and/or contains at least one alkali metal bronze, in particular sodium bronze and/or potassium bronze, preferably with a metal selected from molybdenum, tungsten, tantalum, and/or niobium.

The dopant, in particular sodium ions, is/are advantageously present in the contact layer and/or in the semiconductor absorber layer in a dose in the range of 10¹³ to 10¹⁷ atoms/cm², in particular in the range of 10¹⁴ to 10¹⁶ atoms/cm².

The first buffer layer may be deposited dry or also by wet chemical means. The first buffer layer may contain or be formed essentially from CdS or a CdS-free layer, in particular containing or composed essentially of Zn(S,OH) or In₂S₃. The second buffer layer preferably contains or is formed essentially from intrinsically conductive zinc oxide and/or high-resistance zinc oxide.

The material used for the front electrode is preferably transparent to electromagnetic radiation, in particular to radiation having a wavelength in the range of the absorption wavelength range of the semiconductor. Suitable front electrode materials for photovoltaic thin-film solar cells and their application are known to those skilled in the art. In one specific embodiment, the front electrode contains or is formed essentially from n-doped zinc oxide.

In particularly suitable embodiments, thin-film solar modules according to the present invention are also characterized in that the average thickness of the back electrode layer is in the range of 50 nm to 500 nm, in particular in the range of 80 nm to 250 nm, and/or the average thickness of the barrier layer is in the range of 10 nm to 250 nm, in particular in the range of 20 nm to 150 nm, and/or the average thickness of the contact layer is in the range of 2 nm to 200 nm, in particular in the range of 5 nm to 100 nm, and/or the average thickness of the semiconductor absorber layer is in the range of 400 nm to 2,500 nm, in particular in the range of 500 nm to 2,000 nm, and preferably in the range of 800 nm to 1,600 nm, and/or the average thickness of the first buffer layer is in the range of 5 nm to 100 nm, in particular in the range of 10 nm to 70 nm, and/or the average thickness of the second buffer layer is in the range of 10 nm to 150 nm, in particular in the range of 20 nm to 100 nm. The overall thickness of the multilayer back electrode, i.e., the system made up of the back electrode or bulk back electrode, barrier layer, and contact layer, should preferably be set in such a way that the overall specific resistance of this multilayer back electrode does not exceed 50 microohms*cm, preferably 10 microohms*cm. Under these criteria, ohmic losses in a module connected in series may be further reduced in a particularly efficient way.

Using thin-film solar modules according to the present invention, high efficiencies also result with such specific embodiments in which the back electrode layer contains molybdenum and/or tungsten, in particular molybdenum, or is formed essentially from molybdenum and/or tungsten, in particular molybdenum, the conductive barrier layer contains TiN or is formed essentially from TiN, and the contact layer contains MoSe₂ or is formed essentially from MoSe₂.

In advantageous embodiments of thin-film solar modules according to the present invention, the first, second, third, and/or fourth structuring separating trench(es) has/have an average width, at least in sections, in particular completely, of not greater than 50 μm, in particular not greater than 30 μm, and preferably not greater than 15 μm.

In thin-film solar modules according to the present invention, it may also be provided that in particular adjacent first and second structuring separating trenches and/or in particular adjacent first and third structuring separating trenches and/or in particular adjacent second and third structuring separating trenches, or in particular adjacent first, second, and third structuring separating trenches or in particular adjacent first and fourth structuring separating trenches extend, at least in sections, essentially in parallel.

In addition, in embodiments of the present invention it has proven advantageous for adjacent first structuring separating trenches and/or adjacent second structuring separating trenches and/or adjacent third structuring separating trenches and/or adjacent fourth structuring separating trenches to have an average spacing, at least in sections, in the range of 3 mm to 10 mm, in particular 4 mm to 8 mm.

It may also be provided that adjacent first and second structuring separating trenches and/or adjacent second and third structuring separating trenches and/or adjacent first and fourth structuring separating trenches have an average spacing, at least in sections, in particular completely, in the range of 5 μm to 100 μm, in particular in the range of 10 μm to 50 μm.

Due to the very narrow design which the structuring separating trenches may have and/or due to the small distances between adjacent structuring separating trenches, the effective surface area of a solar cell, i.e., that surface area available for the conversion of solar energy, may be optimized or designed to be preferably large.

In thin-film solar modules according to the present invention, the first structuring separating trenches are generally filled with the insulator material to above the level of the semiconductor absorber layer, in particular to above the level of the buffer layer. The bridge resistance over the first structuring separating trench which is filled with insulator material is preferably greater than 50 kohm, in particular greater than 100 kohm.

At least two, in particular a plurality of, monolithically integrated solar cells connected in series is/are present in thin-film solar modules according to the present invention.

Moreover, the object underlying the present invention is achieved by a method for manufacturing a first embodiment of the thin-film solar module according to the present invention, including:

a) providing an in particular planar substrate layer,
b) applying at least one back electrode layer, in particular to the substrate layer,
c) applying at least one conductive barrier layer, in particular to the substrate layer or to the back electrode layer, or to the substrate layer and to the back electrode layer, in particular to the back electrode layer, which has been applied directly to the substrate layer,
d) applying at least one, in particular ohmic, contact layer, in particular to the barrier layer,
e) applying at least one, in particular kesterite or chalcopyrite, semiconductor absorber layer, in particular to the contact layer,
f) optionally applying at least one first buffer layer, in particular to the semiconductor absorber layer,
g) optionally applying at least one second buffer layer, in particular to the first buffer layer or to the semiconductor absorber layer,
h) applying at least one front electrode layer, in particular to the semiconductor absorber layer or to the first or second buffer layer,
i) at least one first structuring step which includes removing the layers applied to the substrate layer, along spaced-apart lines with the aid of laser treatment (first laser treatment), with formation of first structuring separating trenches which separate adjacent solar cells,
j) at least one second structuring step which includes
j1) removing those layers which extend from the contact layer or from the back electrode layer or from the barrier layer, in particular from the barrier layer, up to and including the front electrode layer, along spaced-apart lines, with formation of second structuring separating trenches which are adjacent to first structuring separating trenches or which abut on same, and in particular which extend, at least in sections, essentially in parallel to same, or
j2) chemical phase transformation and/or thermal decomposition of those layers which extend from the contact layer or from the back electrode layer or from the barrier layer, in particular from the barrier layer, up to and including the front electrode layer, along spaced-apart lines, with formation of first linear conductive areas which are adjacent to first structuring separating trenches or which abut on same, and in particular which extend, at least in sections, essentially in parallel to same,
k) at least one third structuring step which includes removing the layers which extend from the contact layer or from the back electrode layer or from the barrier layer, in particular from the barrier layer, up to and including the front electrode layer, along spaced-apart lines, with formation of third structuring separating trenches which are adjacent to second structuring separating trenches or which abut on same, and in particular which extend, in sections, essentially in parallel to same,
l) filling the first structuring separating trenches with at least one insulator material,
m) filling the second structuring separating trenches with at least one conductive material,
n) forming at least one conductive bridge, using a conductive material, from the second structuring separating trenches which are filled with conductive material, or from the first linear conductive areas over adjacent first structuring separating trenches which are filled with the insulator material, to the front electrode layer of the solar cell that is adjacent thereto, so that adjacent solar cells are electrically connected in series.

Moreover, the object underlying the present invention is also achieved by a method for manufacturing a second embodiment of a thin-film solar module according to the present invention, including:

a) providing an in particular planar substrate layer,
b) applying at least one back electrode layer, in particular to the substrate layer,
c) applying at least one conductive barrier layer, in particular to the substrate layer or to the back electrode layer, or to the substrate layer and to the back electrode layer, in particular to the back electrode layer, which has been applied directly to the substrate layer,
d) applying at least one, in particular ohmic, contact layer, in particular to the barrier layer,
e) applying at least one, in particular kesterite or chalcopyrite, semiconductor absorber layer, in particular to the contact layer,
f) optionally applying at least one first buffer layer, in particular to the semiconductor absorber layer,
g) optionally applying at least one second buffer layer, in particular to the first buffer layer or to the semiconductor absorber layer,
h) applying at least one front electrode layer, in particular to the semiconductor absorber layer or to the first or second buffer layer,
i) at least one first structuring step which includes removing the layers applied to the substrate layer, along spaced-apart lines with the aid of laser treatment (first laser treatment), with formation of first structuring separating trenches which separate adjacent solar cells,
o) at least one fourth structuring step which includes removing those layers which extend from the contact layer or from the back electrode layer or from the barrier layer, in particular from the barrier layer, up to and including the front electrode layer, along spaced-apart lines, with formation of fourth structuring separating trenches which are adjacent to first structuring separating trenches or which abut on same, and in particular which extend, at least in sections, essentially in parallel to same,
p) filling the first structuring separating trenches with at least one insulator material,
q) filling a first volume area of the fourth structuring separating trenches, which extends from the barrier layer to the front electrode layer along the separating trench wall adjacent to the first structuring separating trench, with at least one conductive material, while not filling/leaving open a second volume area adjacent thereto which extends from the barrier layer to the front electrode layer along that separating trench wall which is not adjacent to the first structuring separating trench,
r) forming at least one conductive bridge, using a conductive material, from the first volume areas of the fourth structuring separating trenches which are filled with conductive material, over adjacent first structuring separating trenches which are filled with the insulator material, to the front electrode layer of the solar cell that is adjacent thereto, so that adjacent solar cells are electrically connected in series.

In the manufacture of the first embodiment of the thin-film solar module according to the present invention, filling the second structuring separating trenches with at least one conductive material and forming at least one conductive bridge, using a conductive material, from the second structuring separating trenches which are filled with conductive material, over adjacent first structuring separating trenches which are filled with the insulator material to the front electrode layer of the solar cell adjacent thereto, so that adjacent solar cells are connected in series, may also be carried out in one method step or one work operation; i.e., steps m) and n) may also be combined into a step s).

In addition, in the manufacture of the first embodiment of the thin-film solar module according to the present invention it is possible for the sequence of steps i), j1), k), l), and m) to be arbitrary as long as l) comes directly or indirectly after i), and m) comes directly or indirectly after j1), or for the sequence of steps i), j2), k), and l) to be arbitrary as long as l) comes directly or indirectly after i). The sequence is preferably i), j1), l), k), m), and n), or i), j1), l), k), and s), or i), j2), l), k), and n).

The chemical phase transformation in step j2) is preferably carried out by thermal decomposition of those layers which extend from the barrier layer up to and including the front electrode layer, in particular with the aid of laser treatment. The conductivity of the mentioned layers compared to the adjacent untreated layers is thus greatly increased along lines which are treated with laser light, for example. This allows these linearly treated layers, similarly as for second structuring separating trenches which are filled with conductive material, to be utilized for contacting in the electrical series connection of adjacent solar cells. Laser light wavelengths and pulse durations which are suitable for the phase transformation are known to those skilled in the art. Suitable pulse durations are greater than 1 nanosecond, for example.

In the manufacture of the second embodiment of the thin-film solar module according to the present invention, filling the first volume areas of the second structuring separating trenches with at least one conductive material and forming at least one conductive bridge, using a conductive material, from the first volume area which is filled with conductive material, over adjacent first structuring separating trenches which are filled with the insulator material, to the front electrode layer of the solar cell adjacent thereto, so that adjacent solar cells are connected in series, may also be carried out in one method step or one work operation; i.e., steps q) and r) may also be combined into a step t).

In addition, in the manufacture of the second embodiment of the thin-film solar module according to the present invention it is possible for the sequence of steps i), o), p), and q) to be arbitrary as long as p) comes directly or indirectly after i), and q) comes directly or indirectly after o). The sequence is preferably i), o), p), q), and r), or i), o), p), and t).

In one refinement, method steps i) and j1), i) and j2), i) and k), j1) and k), j2) and k), i), j1), and k), and/or i), j2), and k) may also be carried out at the same time. In addition, steps i) and o) may also be carried out at the same time.

In one particularly suitable specific embodiment, the substrate is transparent, at least in part, to electromagnetic radiation of the first laser treatment. This laser treatment in the first structuring step, in particular by laser ablation, may advantageously take place from the side facing away from the coated side of the substrate.

In another specific embodiment of the method according to the present invention, it is provided that the second, third, or fourth structuring separating trench is produced in the second and/or third and/or fourth structuring step(s), in particular the second structuring step, with the aid of laser treatment (second, third, or fourth laser treatment), and/or that the second, third, or fourth structuring separating trench is produced mechanically, in particular with the aid of needle scoring, in the second and/or third and/or fourth structuring step(s), in particular the third and/or fourth structuring step(s).

According to one particularly advantageous specific embodiment of the method according to the present invention, it is provided that the first, second, third, and/or fourth structuring separating trench(es) and/or the first linear conductive areas are produced at least in sections, in particular completely, with an average width of not greater than 50 μm, in particular not greater than 30 μm, and preferably not greater than 15 μm.

One refinement of the method according to the present invention also provides that in particular adjacent first and second structuring separating trenches and/or in particular adjacent first and third structuring separating trenches and/or in particular adjacent second and third structuring separating trenches or in particular adjacent first, second, and third structuring separating trenches or in particular adjacent first and fourth structuring separating trenches or in particular adjacent first structuring separating trenches and first linear conductive areas are led, at least in sections, essentially in parallel.

Furthermore, a method procedure has proven to be advantageous in which adjacent first structuring separating trenches and/or adjacent second structuring separating trenches and/or adjacent third structuring separating trenches and/or adjacent fourth structuring separating trenches and/or adjacent first linear conductive areas are produced with an average spacing, at least in sections, in the range of 3 mm to 10 mm, in particular 4 mm to 8 mm.

Using the method according to the present invention, in another specific embodiment it is also possible to produce adjacent first and second structuring separating trenches and/or adjacent second and third structuring separating trenches and/or adjacent first and fourth structuring separating trenches and/or adjacent first structuring separating trenches and first linear conductive areas with an average spacing, at least in sections, in particular completely, in the range of 5 μm to 100 μm, in particular in the range of 10 μm to 50 μm.

In this regard, one such specific embodiment is particularly suitable in which adjacent first, second, and third structuring separating trenches or adjacent first and fourth structuring separating trenches or adjacent first structuring separating trenches and first linear conductive areas have a smaller average distance from one another than nonadjacent first, second, and third structuring separating trenches or nonadjacent first and fourth structuring separating trenches or nonadjacent first structuring separating trenches and first linear conductive areas.

In the first embodiment of the method according to the present invention, third structuring separating trenches, in particular all third structuring separating trenches, are generally separated from the particular adjacent first structuring separating trench by the particular adjacent second structuring separating trench or the first linear conductive area.

In the production of the structuring separating trenches, the first laser treatment, the second laser treatment, and/or the third laser treatment preferably take(s) place using laser light pulses having a pulse duration in the range of 1 picosecond to 1 nanosecond. For example, laser light pulses having a pulse duration of less than 10 picoseconds are used in the method for the first and second laser treatments. A line advance with speeds of several m/s, for example, is suitable for mass production.

The first, second, and third structuring steps of the first embodiment of the method according to the present invention or the first and fourth structuring steps of the second embodiment of the method according to the present invention generally result in or generally contribute to a monolithically integrated series connection of the solar cells. These structuring steps are preferably designed as linear processing steps.

Method procedures have also proven to be particularly advantageous in which the contact layer, in particular containing at least one dopant, contains or is formed essentially from molybdenum, tantalum, zirconium, cobalt, niobium, and/or tungsten (first metal ply), and/or at least one metal chalcogenide selected from metal selenide, metal sulfide, and/or metal sulfoselenide, where the metal is Mo, W, Ta, Zr, Co, or niobium, and in particular is selected from the group composed of MoSe₂, WSe₂, MoS₂, WS₂, Mo(Se₁₋ₓ,Sₓ)₂, and/or W(Se₁₋ₓ,Sₓ)₂, where x assumes any arbitrary value from 0 to 1.

The method according to the present invention preferably provides that the semiconductor absorber layer represents or includes a quaternary IB-IIIA-VIA chalcopyrite layer, in particular a Cu(In,Ga)Se₂ layer, a pentenary IB-IIIA-VIA chalcopyrite layer, in particular a Cu(In,Ga)(Se₁₋ₓ,Sₓ)₂-layer, or a kesterite layer, in particular a Cu₂ZnSn(Seₓ,S₁₋ₓ)₄-layer, such as a Cu₂ZnSn(Se)₄-layer or a Cu₂ZnSn(S)₄-layer, where x assumes values from 0 to 1.

In addition, a procedure has proven to be particularly advantageous in which metals which are present in the contact layer or which form this contact layer are completely or partially converted into metal selenides, metal sulfides, and/or metal sulfoselenides by applying the kesterite or chalcopyrite semiconductor absorber layer to the contact layer.

The method according to the present invention may be carried out, for example, in such a way that the contact layer includes a layer sequence composed of at least one metal layer and at least one metal chalcogenide layer, the metal layer adjoining or abutting on the back electrode layer or the conductive barrier layer, and the metal chalcogenide layer adjoining or abutting on the semiconductor absorber layer. In addition, approaches in which the metal layer and the metal of the metal chalcogenide layer are the same, in particular which represent molybdenum and/or tungsten, are advantageous.

In addition, the method according to the present invention may be designed, for example, in such a way that at least one first metal ply made of molybdenum, tantalum, zirconium, cobalt, tungsten, and/or niobium, for example, is applied to the barrier layer, and that during the production of the semiconductor absorber layer, in particular the kesterite or chalcopyrite semiconductor absorber layer, this first metal ply is partially converted into a metal chalcogenide layer in a selenium- and/or sulfur-containing atmosphere, with formation of the contact layer. Another embodiment of the method according to the present invention further provides that at least one first metal ply made of molybdenum, tantalum, tungsten, cobalt, zirconium, and/or niobium is applied to the barrier layer, and that during the production of the semiconductor absorber layer, in particular the kesterite or chalcopyrite semiconductor absorber layer, this first metal ply is completely converted into a metal chalcogenide layer in a selenium- and/or sulfur-containing atmosphere, with formation of the contact layer.

In the method according to the present invention, in one advantageous specific embodiment the step of applying the semiconductor absorber layer, in particular the kesterite or chalcopyrite semiconductor absorber layer, accordingly includes depositing in particular all metallic components of the semiconductor absorber layer, in particular copper, indium, and optionally gallium, for the chalcopyrite semiconductor absorber layer, and copper, zinc, and tin for the kesterite semiconductor absorber layer, on the contact layer with formation of a second metal ply, and treating this second metal ply with selenium and/or a selenium compound and optionally with sulfur and/or a sulfur compound, preferably at temperatures above 300° C., in particular above 350° C.

During the production of the semiconductor absorber layer, the conversion temperatures are frequently even in the range of 500° C. to 600° C. At such temperatures, dopants, such as sodium ions or sodium compounds in particular, migrate, in particular diffuse, from the doped contact layer into the semiconductor absorber layer. As a result of the barrier layer, migration or diffusion into the back electrode layer does not take place. Due to the mentioned relatively high temperatures in the processing of the semiconductor, it is advantageous that the selected layers of the multilayer back electrode, in particular the back electrode and/or the conductive barrier layer, have a composition such that their linear coefficient of thermal expansion is adapted to that of the semiconductor absorber and/or the substrate. Therefore, the composition in particular of the back electrode and/or the barrier layer of the thin-film solar modules according to the present invention should preferably be such that a linear coefficient of thermal expansion of 14*10⁻⁶ K, preferably 9*10⁻⁶ K, is not exceeded.

In the method according to the present invention, it may also be provided that the back electrode layer, the conductive barrier layer, the first metal ply, in particular containing Mo, the contact layer, the second metal ply, in particular containing Cu, In, and Ga, the first buffer layer, the second buffer layer, and/or the front electrode layer is/are obtained with the aid of physical gas phase deposition, in particular including physical vapor deposition (PVD) coating, vapor deposition with the aid of an electron beam evaporator, vapor deposition with the aid of a resistance evaporator, induction evaporation, ARC evaporation, and/or cathode sputtering (sputter coating), in particular DC or RF magnetron sputtering, in each case preferably in a high vacuum, or with the aid of chemical gas phase deposition, in particular including chemical vapor deposition (CVD), low pressure CVD, and/or atmospheric pressure CVD.

It is particularly advantageous that the application of the back electrode layer, the conductive barrier layer, the first metal ply, or the contact layer and the second metal ply may take place in particular in a single vacuum coating unit, preferably in the continuous sputtering process.

In addition, in the method according to the present invention it is advantageous that the first and second structuring steps and the step of filling the first structuring separating trench with the insulator material may take place in a single unit. The structuring steps of the method according to the present invention as well as the filling steps, provided that they do not have to logically follow one another in succession, may take place or be carried out in segments, or also all at the same time. For example, multilayer head systems for laser and ink jet or aerosol jet devices, via which multiple trenches may be processed and filled at the same time, may be used for this purpose.

According to the present invention, it may be preferred that for applying conductive or other structures with the aid of laser and ink jet or aerosol jet devices according to the present invention, an ink, preferably a hot melt aerosol ink, is atomized and a conductive contact is thus applied to the substrate, the laser and ink jet or aerosol jet devices being at least partially heatable or heated, preferably with the condition that the ink used has a viscosity of Θ≦1 Pas at a temperature of at least 40° C. This is described in published German patent application document DE 10 2007 058 972 A1, for example, which is incorporated herein by this reference.

It may be advantageous when an ink for the ink jet and/or the aerosol jet device(s) in particular contains metal particles, in particular metal particles selected from a group composed of silver, tin, zinc, chromium, cobalt, tungsten, titanium, and/or their mixtures. Alternatively or additionally, the ink may contain the metal oxides, such as lead oxide, bismuth oxide, titanium oxide, aluminum oxide, magnesium oxide, and/or their mixtures.

It may also be advantageous when the ink contains thermoplastic compounds selected from the group composed of C₁₆ to C₂₀, preferably C₁₄ to C₁₆, linear aliphatic alcohols and/or polyhydric alcohols such as hexane-1,6-diol.

According to the present invention, it may also be preferred that the solvent contained in the ink is selected from glycol ether, M-methylpyrrolidone, 2-(2-butoxyethoxy)ethanol, and/or their mixtures.

It may also be preferred that the ink contains a dispersing agent and/or a defoamer as additives.

The structuring separating trenches may be produced, for example, over the length of a thin-film solar module in one continuous work operation. For example, structuring separating trenches having a length of 1.6 m and greater may be obtained in this way. The length of the structuring separating trenches may be limited, for example, by the length of the module or substrate or by plant engineering constraints, but not, however, by the method according to the present invention itself.

In one preferred specific embodiment, filling the first structuring separating trench with the insulator material and/or filling the second structuring separating trench or the first volume area of the fourth structuring separating trench with conductive material take(s) place using the ink jet method or the aerosol jet method. With the ink jet method, the insulator material as well as the conductive material may be very finely dosed, as known from the ink jet printer industry, for example. For example, with the aid of the ink jet method and/or the aerosol jet method, droplets having a volume in the range of approximately 10 picoliters to less than one picoliter may be finely dosed, and, with precise adjustment using a precision XYZ table, for example, filled or injected into the structuring separating trenches. In addition, such low drop volumes also allow only partial filling of a structuring separating trench, for example via drop size, drop rate, and/or advance and/or by appropriate lateral adjustment. For example, the second structuring separating trench may have a height of approximately 3 microns with a width of approximately 20 microns. With such an aspect ratio, it is easily possible, for example, in a single work operation to completely fill the first structuring separating trench with insulator material, and to fill the second structuring separating trench partially, i.e., in the first volume area, with conductive material, and also to form a conductive bridge from this filled first volume area to the front electrode of the adjacent solar cell.

For example, a quick-curing insulator ink or a UV-curing, electrically insulating lacquer as known from semiconductor technology may be used as filling material. The UV illumination preferably takes place immediately after the filling step.

The present invention is based on the surprising finding that, due to the sequence of the structuring processes, in particular in combination with the one multilayer back electrode containing a bidirectional barrier layer in particular, photovoltaic thin-film solar modules which include monolithically integrated solar cells connected in series may be obtained in mass production in high quality and with high efficiencies in a cost-efficient and reproducible manner. In this regard, it is also advantageous that the cell and module format design are also variable over a wide range, even in mass production, and appropriate customer requests may be taken into account and implemented to a great extent. This likewise applies to the off-load voltage and the short-circuit current for a thin-film solar module requested by the customer. As a result of the structuring of the solar cells taking place only after all layers up to the front electrode layer have been deposited, there are also no points of vulnerability for damage during manufacturing of the semiconductor absorber layer, which regularly occurs under aggressive conditions, i.e., at high temperatures and in the presence of hydrogen selenide, hydrogen sulfide, elemental selenium vapor, and/or elemental sulfur vapor, for example. For example, infiltration of individual layers with formation of metal chalcogenides may be precluded. This is because in the methods known from the related art, the structuring trenches are produced prior to the semiconductor formation process, for which reason the structuring trenches are under the effect of the high temperatures in the range of 350° C. to 600° C. used in the semiconductor formation, and optionally also alkali diffusion, and then frequently corrode under the effect of selenium or sulfur. This results in layer infiltration and the formation of microcracks due to mechanical stress caused by the volume expansion of the metals which are corroded under the effect of selenium and/or sulfur. These disadvantages are avoided with the method according to the present invention. This results in thin-layer systems having improved adhesion and a layered structure composed of individual layers which are characterized by a flatter surface compared to thin-film solar modules obtained according to methods known from the related art. Boundary surface roughness and layer thickness fluctuations are no longer observed. In addition, separate back electrodes are no longer present during the formation of the semiconductor absorber layer, so that there is no longer concern for surface corrosion at the flanks of the structuring separating trench. The risk of microcracks is thus reduced or even eliminated. In addition, the formation of a structuring edge during the laser structuring due to melting of the back electrode metal may be avoided. Such a melting edge is generally particularly susceptible to a reaction with selenium and/or sulfur under the conditions for forming the semiconductor absorber layer. A pronounced volume expansion resulting in microcracks often cannot be prevented. These types of problems no longer occur with the thin-film solar modules according to the present invention.

In the thin-film solar modules according to the present invention, it is also advantageous that a preferably large photovoltaically active surface area which may be utilized for energy recovery may be reliably provided for each solar cell. The structuring separating trenches, which may be designed to be very narrow, as well as the distances between adjacent structuring separating trenches, which are settable to a minimum distance, contribute in this regard.

The method according to the present invention also allows the damage to the insulating barrier layer, which otherwise frequently occurs in the laser process, to be avoided. Consequently, alkali ions may be prevented from passing from the substrate glass into the semiconductor absorber layer in an uncontrolled manner. As the result of avoiding overdoping of the semiconductor absorber layer and filling the structuring trench with insulator filling material, the desired high bridge resistance between adjacent cells is greatly improved over the related art, resulting in a significant gain in the filling factor and the efficiency. In addition, the controlled doping of the semiconductor absorber layer ensures that adhesion problems, induced by alkali ions, in the individual layers in the thin-film solar module obtained according to the method according to the present invention no longer occur. The proportion of unusable rejects may thus be drastically reduced.

Larger filling factors and improved efficiencies may be achieved by use of the thin-film solar modules according to the present invention.

It has also proven to be advantageous to have multiple method steps carried out in a single unit. This applies, for example, to the first and second structuring steps and the filling of the first structuring separating trench with an insulator material. The method according to the present invention thus allows more cost-effective processing with a marked improvement in performance. In addition, the semiconductor absorber layer may be provided with dopants in a much more targeted manner.

Further features and advantages of the present invention result from the following description, in which preferred specific embodiments of the present invention are explained as an example with reference to schematic drawings.

### BRIEF DESCRIPTION OF THE DRAWINGS

FIG. 1 shows a schematic cross-sectional view of a manufacturing stage of a first specific embodiment of the thin-film solar module according to the present invention, obtained according to a first specific embodiment of the method according to the present invention.

FIG. 2 shows a schematic cross-sectional view of a subsequent manufacturing stage of the thin-film solar module according to the present invention, obtained according to the method according to the present invention.

FIG. 3 shows a schematic cross-sectional view of a further manufacturing stage of the thin-film solar module according to the present invention, obtained according to the method according to the present invention.

FIG. 4 shows a schematic cross-sectional view of a further manufacturing stage of the thin-film solar module according to the present invention, obtained according to the method according to the present invention.

FIG. 5 shows a schematic cross-sectional view of a further manufacturing stage of the thin-film solar module according to the present invention, obtained according to the method according to the present invention.

FIG. 6 shows a schematic cross-sectional view of a further manufacturing stage of the thin-film solar module according to the present invention, obtained according to the method according to the present invention.

FIG. 7 shows a schematic cross-sectional view of a manufacturing stage of one alternative specific embodiment of the thin-film solar module according to the present invention, obtained according to one alternative specific embodiment of the method according to the present invention.

FIG. 8 shows a schematic cross-sectional view of a further manufacturing stage of the alternative specific embodiment of the thin-film solar module according to the present invention, building on the manufacturing stage according to FIG. 7.

FIG. 9 shows a schematic cross-sectional view of a manufacturing stage of another alternative specific embodiment of the thin-film solar module according to the present invention, obtained according to one alternative specific embodiment of the method according to the present invention.

FIG. 10 shows a schematic cross-sectional view of a further manufacturing stage of the alternative specific embodiment of the thin-film solar module according to the present invention, building on the manufacturing stage according to FIG. 9.

### DETAILED DESCRIPTION OF THE INVENTION

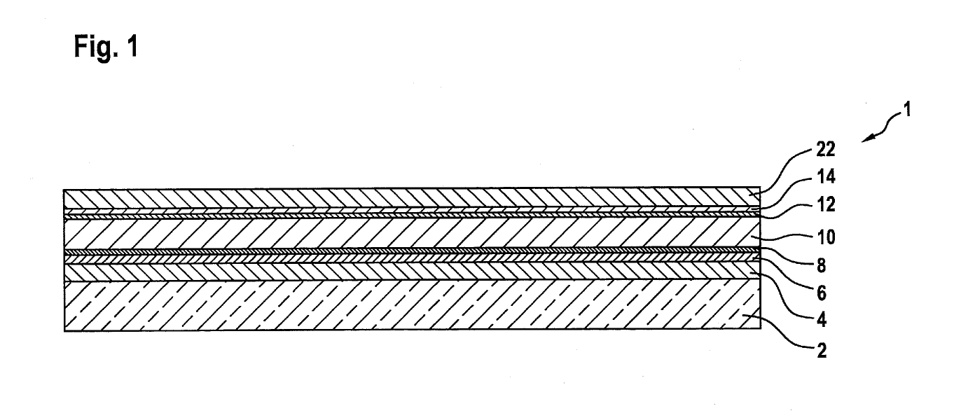

FIG. 1 shows a schematic cross-sectional view of an intermediate manufacturing stage 1a of a thin-film solar module 1 according to the present invention. A bulk back electrode layer 4 made of molybdenum, for example, with the aid of thin-film deposition is present on glass substrate 2. The bulk back electrode layer is adjoined by a bidirectional reflective barrier layer 6 made of TiN or ZrN, for example, which likewise may be obtained with the aid of thin-film deposition. In the illustrated specific embodiment, an ohmic contact layer 8 made of a metal chalcogenide such as molybdenum selenide is situated on barrier layer 6. This contact layer may be obtained in various ways, as explained above in a general way. In one embodiment, for example, molybdenum selenide from a molybdenum selenide target has been sputtered on. Alternatively, initially a metal layer may be applied which is subsequently converted into the corresponding metal chalcogenide prior to and/or during the formation of the semiconductor absorber layer. In one preferred specific embodiment, contact layer 8 may also be combined with at least one dopant such as sodium ions or a sodium compound, in particular sodium sulfite or sodium sulfide. Layer 10 represents the semiconductor absorber layer, and may be present, for example, as a chalcopyrite semiconductor absorber layer or as a kesterite semiconductor absorber layer. Methods for applying these semiconductor absorber layers are known to those skilled in the art. If a dopant is present in the contact layer, the dopant generally diffuses into the semiconductor absorber layer under the conditions for forming the latter. This is followed by initial application of first buffer layer 12 made of CdS, Zn(S,OH), or In₂S₃, for example, and second buffer layer 14, made of intrinsic zinc oxide, and subsequent application of front electrode layer 22, made of n-doped zinc oxide, to semiconductor absorber layer 10 with the aid of thin-film deposition.

Layer sequence 2, 4, 6, and 8 of a thin-film solar module 1 according to the present invention, illustrated in FIG. 1, may be produced in a single unit in an essentially continuous process. During the overall process period, processing may take place in a single unit. Thus, not only are costly method steps avoided, but also the risk of contamination of the intermediate product stages with oxygen, for example, is reduced.

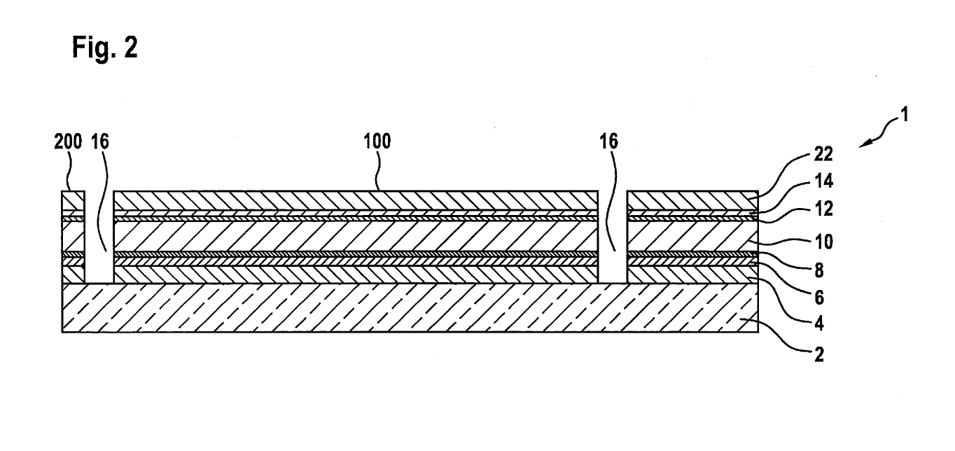

FIG. 2 shows the first structuring step carried out on intermediate manufacturing stage 1a to obtain manufacturing stage 1b. With the aid of laser treatment from the bottom side of transparent substrate 2 (indicated by arrow symbols), first separating trenches 16 have been produced which ultimately determine the widths of the solar cells of the monolithically integrated series connection. Solar cells 100 and 200, for example, are separated from one another by first separating trench 16. In this way, all layers present above the substrate have been removed along lines over an average separating trench width of 15 μm, including the front electrode layer.

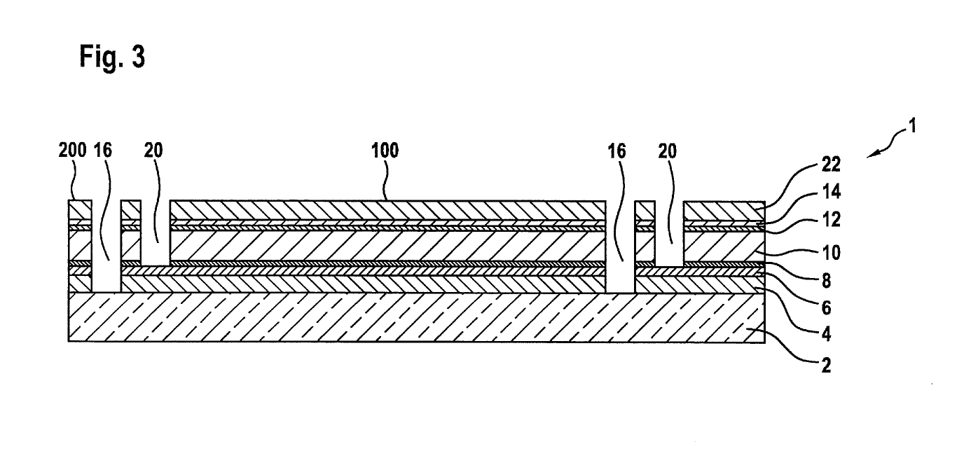

In manufacturing stage 1c depicted in FIG. 3, with the aid of laser treatment a second structuring process has been carried out on the layer system, this time from the top side, with formation of spaced-apart second separating trenches 20. All layers have been removed, preferably over an average width of 15 μm, from front electrode layer 22, via the buffer layers and semiconductor absorber layer 10, up to and including contact layer 8. These second separating trenches 20 may also be produced mechanically, for example with the aid of needle scoring. The second separating trenches are applied adjacent to first separating trenches 16, and have an average spacing, for example, of less than 50 μm, approximately 30 μm, for example. In the present case, first and second separating trenches 16, 20 are preferably situated essentially in parallel.

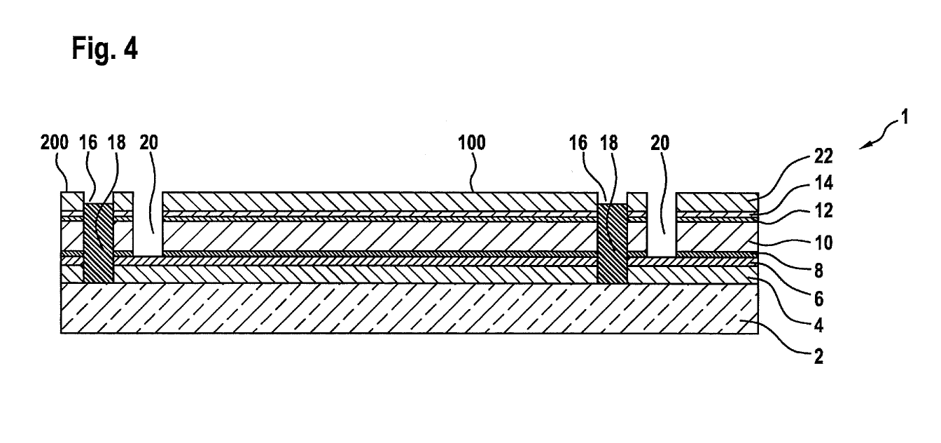

As shown in FIG. 4, with the aid of ink jet or aerosol jet methods, for example, first separating trenches 16 may be filled with an insulator material 18 which is curable with UV light, for example. As shown in FIG. 4, the first separating trench should preferably be filled with insulator material 18 up to front electrode layer 22, i.e., above second buffer layer 14, in order to avoid subsequent short circuits in the wall area of the structuring flank on the side facing cell 200. Manufacturing stage 1d is obtained.

The steps of the first and second laser structuring as well as the filling of the first separating trenches may preferably be carried out in the same unit. Laborious adjustment is thus dispensed with, and instead has to be carried out only once. In addition, the first and second separating trenches may be applied at a smaller distance from one another, thus enlarging the photovoltaically active surface area of the thin-film solar module.

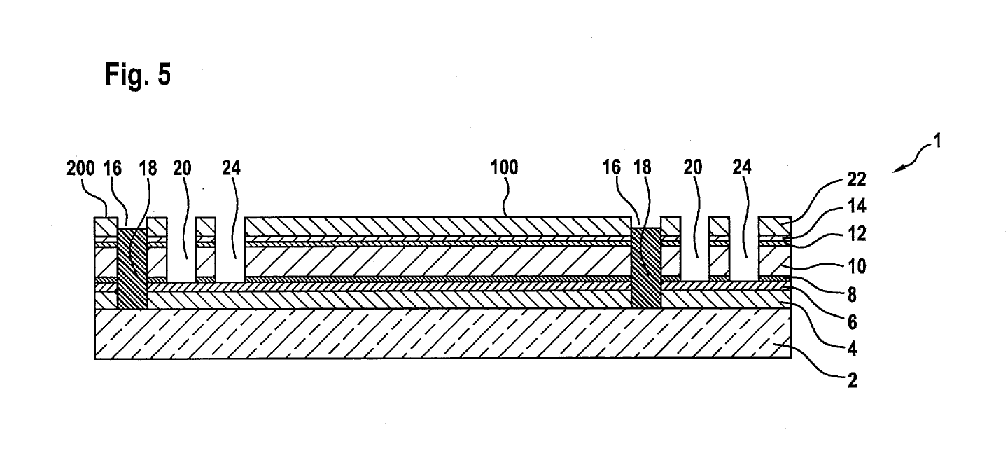

Manufacturing stage 1d subsequently undergoes the third structuring step for the purpose of defining the insulation structure in the monolithically integrated series connection, in which third separating trenches 24 which, the same as second separating trenches 20, extend to barrier layer 6, are produced (manufacturing stage 1e; see FIG. 5). The third separating trenches are applied adjacent to second separating trenches 20, and have an average spacing, for example, of less than 50 μm, for example approximately 30 μm. In the present case, second and third separating trenches 20, 24, respectively, are preferably situated essentially in parallel. Third separating trenches 24 may be obtained with the aid of laser treatment or mechanically, for example with the aid of needle scoring. First, second, and third separating trenches 16, 20, and 24, respectively, of solar cell 100 form mutually adjacent separating trenches within the meaning of the present invention.

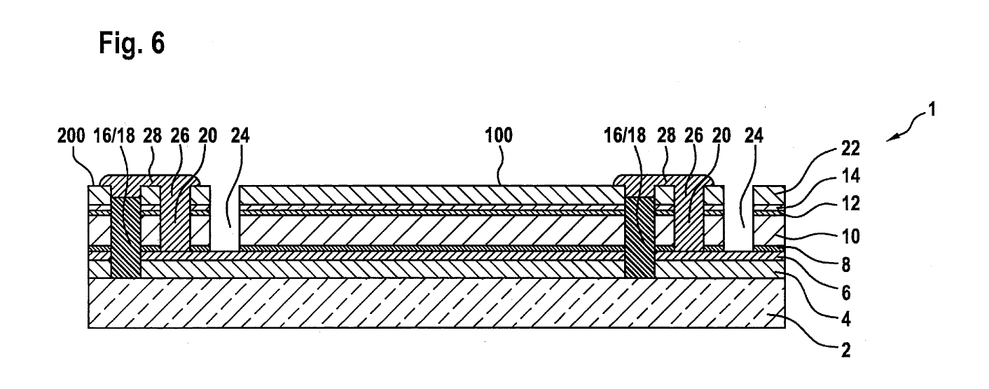

In the illustrated specific embodiment, in the next method stage depicted in FIG. 6, second separating trenches 20 are precisely filled with a highly conductive material 26, and at the same time a conductive bridge 28 containing this conductive material 26 is produced along the surface of front electrode layer 22, over first separating trench 16 which is filled with insulator material 18, to adjacent solar cell 200, for example, to front electrode layer 22 of this solar cell 200. An electrically conductive contact between back electrode 4 of first solar cell 100 to front electrode 22 of adjacent solar cell 200, and thus a series connection, is ensured in this way. The conductive material may be applied with the aid of ink jet or aerosol jet methods, for example. Manufacturing stage 1f is obtained.

In one advantageous embodiment, in the illustrated method the target formats of the thin-film solar modules may be obtained by cutting out of the original format of the substrate after manufacturing stage 1f.

Prior to or after the cutting of the modules, further customary method stages may be connected, for example, the application of a laminating film and/or the mounting of a protective glass layer. These method stages per se are familiar to those skilled in the art.

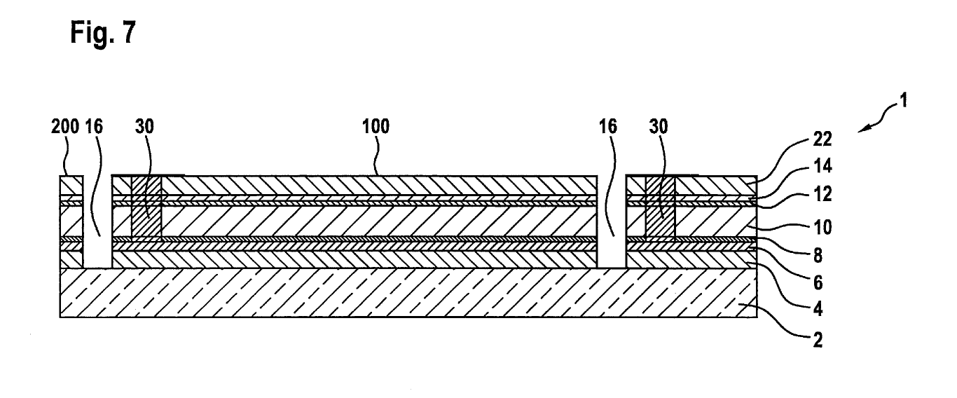

FIG. 7 shows one alternative to manufacturing stages 1c and 1f described above. Instead of initially producing second separating trench 20 in order to subsequently fill it with conductive material, with the aid of targeted laser treatment limited, for example, to the width of the described second separating trench in the preceding first specific embodiment, a highly conductive area 30, preferably in parallel to first separating trench 16, may be produced which forms a conductive path from back electrode 4 to front electrode 22. Due to the thermal input, which is spatially limited to area 30, in the present case a phase transformation of the layers above the barrier layer into the highly conductive path is brought about with the aid of pulsed laser light.

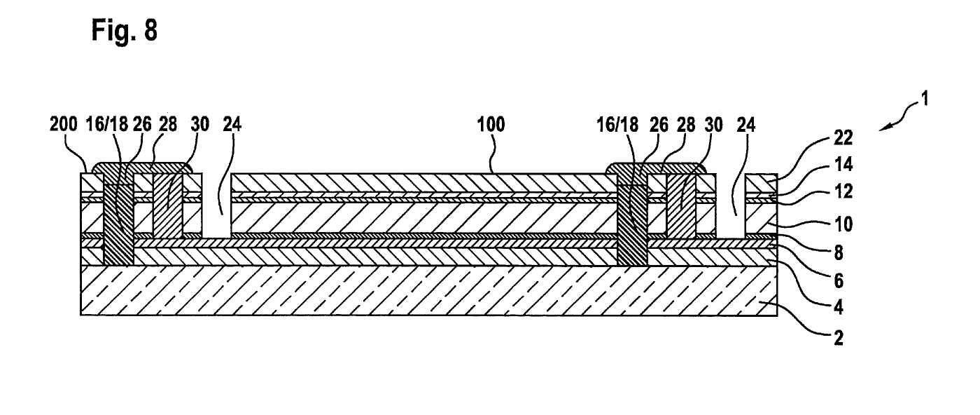

As summarized in FIG. 8, corresponding to manufacturing stages 1d and 1e, first separating trench 16 may then initially be filled with insulator material 18, and third separating trench 24 may be subsequently produced mechanically or with the aid of laser treatment. Similarly as for manufacturing stage 1f described above, this is followed by the attachment of a bridge 28, made of conductive material 26, from first highly conductive area 30 of first solar cell 100 to front electrode layer 22 of adjacent second solar cell 200, over first separating trench 16 which is filled with insulator material 18. In this way as well, a series connection of respectively adjacent solar cells of thin-film solar module 1 according to the present invention is obtained.

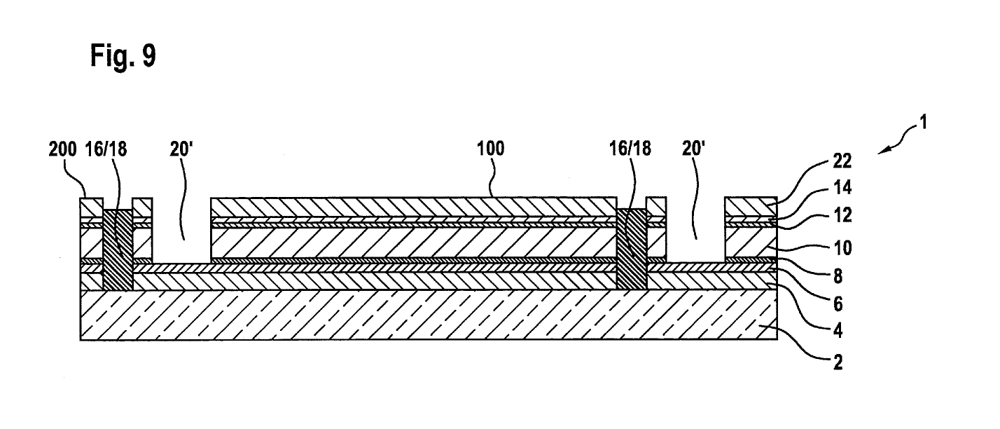

FIG. 9 shows another alternative for obtaining the thin-film solar modules according to the present invention. Initially, a procedure similar to above-described manufacturing stages 1a through 1e is followed; i.e., first and second separating trenches 16 and 20, respectively, are produced and first separating trench is filled with an insulator material 18. In contrast to the procedure of the method according to the present invention shown in FIG. 1 through FIG. 5, second separating trench 20′ of the specific embodiment according to FIG. 9 has a wider design than second separating trench 20 according to FIG. 5. In the case of a locally precise method for applying conductive material 26, as provided by an ink jet or aerosol jet method, for example, in this specific embodiment, second separating trench 20′ may also have a design which is not wider than in the preceding specific embodiments according to FIGS. 1 through 5.

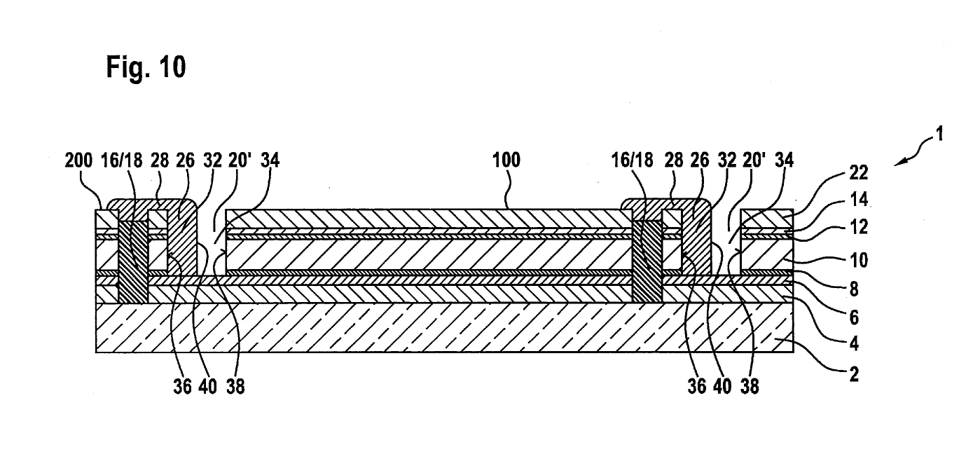

In the subsequent method step, as shown in FIG. 10, a first volume area 32 of second separating trench 20′ is precisely filled with a curable conductive material 26, in particular leaving open/omitting adjacent second volume area 34. At the same time, in this method step a conductive bridge 28, made of conductive material 26, from first volume area 32, which is filled with conductive material 26, of first solar cell 100 to front electrode layer 22 of adjacent second solar cell 200 over first separating trench 16, which is filled with insulator material 18, is produced. In this way as well, a series connection of respectively adjacent solar cells of thin-film solar module 1 according to the present invention is obtained. First volume area 32 extends from first separating trench wall 36, adjoining adjacent first separating trench 16, to a wall area 40 of conductive material 26, at a distance from oppositely situated second separating trench wall 38 of second separating trench 20′. Second volume area 34 accordingly extends from second separating trench wall 38 to wall area 40. Both volume areas begin at barrier layer 6 and extend in a transverse orientation of thin-film solar module 1, up to and including front electrode 22. Contact of first volume area 32 with second separating trench wall 38 is to be avoided in order to avoid short circuits.

1-45. (canceled)

46. A photovoltaic thin-film solar module which comprises, in the following sequence:
at least one substrate layer,
at least one back electrode layer directly adjoining the substrate layer,
at least one conductive barrier layer directly adjoining at least one of the back electrode layer and the substrate layer,
at least one ohmic contact layer directly adjoining the barrier layer,
at least one of a chalcopyrite or kesterite semiconductor absorber layer directly adjoining the contact layer,
at least one first buffer layer directly adjoining the semiconductor absorber layer and
containing one of Zn(S,OH) or In₂S₃,
at least one second buffer layer directly adjoining one of the semiconductor absorber layer or the first buffer layer and containing at least one of intrinsic zinc oxide and high-resistance zinc oxide,
at least one transparent front electrode layer directly adjoining one of the semiconductor absorber layer, the first buffer layer, and the second buffer layer, the at least one transparent front electrode containing n-doped zinc oxide,
spaced-apart first structuring separating trenches which are filled with at least one insulator material and which separate adjacent solar cells from one another up to the substrate layer,
spaced-apart second structuring separating trenches which are filled with at least one conductive material and which extend to one of the contact layer, the back electrode layer, or the barrier layer, and which in each case are situated adjacent to a filled first structuring separating trench,
spaced-apart third structuring separating trenches which extend to one of the contact layer, the back electrode layer, or the barrier layer, and which in each case are situated adjacent to a second structuring separating trench, on the opposite side of the first structuring separating trench which adjoins the second structuring separating trench, and
at least one conductive bridge which extends from second structuring separating trenches which are filled with the conductive material, over adjacent first structuring separating trenches which are filled with the insulator material, to the front electrode layer of the adjacent solar cell.

47. A photovoltaic thin-film solar module which comprises, in the following sequence:
at least one substrate layer,
at least one back electrode layer directly adjoining the substrate layer,
at least one conductive barrier layer directly adjoining at least one of the back electrode layer and the substrate layer,
at least one ohmic contact layer directly adjoining the barrier layer,
at least one of a chalcopyrite or kesterite semiconductor absorber layer directly adjoining the contact layer,
at least one first buffer layer directly adjoining the semiconductor absorber layer and
containing one of Zn(S,OH) or In₂S₃,
at least one second buffer layer directly adjoining one of the semiconductor absorber layer or the first buffer layer and containing at least one of intrinsic zinc oxide and high-resistance zinc oxide,
at least one transparent front electrode layer directly adjoining one of the semiconductor absorber layer, the first buffer layer, and the second buffer layer, the at least one transparent front electrode containing n-doped zinc oxide,
spaced-apart first structuring separating trenches which are filled with at least one insulator material and which separate adjacent solar cells from one another up to the substrate layer,
spaced-apart second structuring separating trenches which extend to one of the contact layer, the back electrode layer, or the barrier layer, and which in each case are situated adjacent to a filled first structuring separating trench, and which include (i) a first volume area which extends from the barrier layer to the front electrode layer along the separating trench wall adjacent to the first structuring separating trench and which is filled with at least one conductive material, and a second volume area which extends from one of the contact layer, the back electrode layer, or the barrier layer, to the front electrode layer, and
at least one conductive bridge which extends from the first volume areas of the second structuring separating trenches which are filled with a conductive material, over adjacent first structuring separating trenches which are filled with an insulator material, to the front electrode layer of the adjacent solar cell.

48. The thin-film solar module as recited in claim 46, wherein the semiconductor absorber layer includes one of a quaternary IB-IIIA-VIA chalcopyrite layer, a pentenary IB-IIIA-VIA chalcopyrite layer, or a kesterite layer.

49. The thin-film solar module as recited in claim 48, wherein the substrate is one of a glass plate, a plastic layer, or a metal plate, having a width greater than 0.5 m and a length greater than 1.2 m.

50. The thin-film solar module as recited in claim 48, wherein the back electrode contains at least one of V, Mn, Cr, Mo, Ti, Co, Zr, Ta, Nb, and W.

51. The thin-film solar module as recited in claim 48, wherein the barrier layer is a bidirectional barrier for diffusible components which migrate through at least one of the back electrode layer and the contact layer.

52. The thin-film solar module as recited in claim 51, wherein the barrier layer is a barrier for alkali ions.

53. The thin-film solar module as recited in claim 51, wherein the barrier layer contains at least one of a metal nitride, a metal silicon nitride, a metal carbide, a metal boride, and a metal silicon nitride.

54. The thin-film solar module as recited in claim 51, wherein the contact layer contains (i) at least one first ply which is adjacent to the barrier layer and which contains at least one of Mo, W, Ta, Nb, Zr, and Co, and (ii) at least one second ply which is not adjacent to the barrier layer and which contains at least one metal chalcogenide.

55. The thin-film solar module as recited in claim 54, wherein the metal of the metal chalcogenide of the second ply of the contact layer includes at least one of molybdenum, tungsten, tantalum, zirconium, cobalt, and niobium, and the chalcogen of the metal chalcogenide includes at least one of selenium and sulfur.

56. The thin-film solar module as recited in claim 55, wherein at least one of:
(i) the metal of the first ply and the metal of the second ply of the contact layer are the same,
(ii) at least one of the metal of the first ply and the metal of the second ply of the contact layer is the same as the metal of the back electrode layer, and
(iii) the metal of the contact layer is the same as the metal of the back electrode layer.

57. The thin-film solar module as recited in claim 51, wherein the semiconductor absorber layer contains at least one of the following dopants: sodium, potassium, lithium, and an alkali metal bronze.

58. The thin-film solar module as recited in claim 57, wherein the dopant is a sodium ion which is present in at least one of the contact layer and the semiconductor absorber layer in a dose in the range of 10¹³ to 10¹⁷ atoms/cm².

59. The thin-film solar module as recited in claim 51, wherein the back electrode layer contains at least one of molybdenum and tungsten, the conductive barrier layer contains TiN, and the contact layer contains MoSe₂.

60. A method for manufacturing a thin-film solar module, comprising:
a) providing a planar substrate layer,
b) applying at least one back electrode layer to the substrate layer,
c) applying at least one conductive barrier layer to at least one of the substrate layer and the back electrode layer,
d) applying at least one ohmic contact layer to the barrier layer,
e) applying one of a kesterite or a chalcopyrite semiconductor absorber layer to the contact layer,
f) applying at least one first buffer layer to the semiconductor absorber layer,
g) applying at least one second buffer layer to one of the first buffer layer or the semiconductor absorber layer,
h) applying at least one front electrode layer to one of the semiconductor absorber layer, the first buffer layer, or the second buffer layer,
i) performing at least one first structuring step by removing the layers applied to the substrate layer, along spaced-apart lines with the aid of a first laser treatment, to form first structuring separating trenches which separate adjacent solar cells,
j) performing at least one second structuring step which includes one of:
j1) removing layers which extend from one of the contact layer, the back electrode layer, or the barrier layer, up to and including the front electrode layer, along spaced-apart lines, to form second structuring separating trenches which are adjacent to the first structuring separating trenches and which extend, at least in sections, essentially in parallel to the first structuring separating trenches, or
j2) performing at least one of chemical phase transformation and thermal decomposition of layers which extend from one of the contact layer, the back electrode layer, or the barrier layer, up to and including the front electrode layer, along spaced-apart lines, to form first linear conductive areas which are adjacent to the first structuring separating trenches and which extend, at least in sections, essentially in parallel to the first structuring separating trenches,
k) performing at least one third structuring step which includes removing layers which extend from one of the contact layer, the back electrode layer, or the barrier layer, up to and including the front electrode layer, along spaced-apart lines, to form third structuring separating trenches which are adjacent to the second structuring separating trenches and which extend, in sections, essentially in parallel to the second structuring separating trenches,
l) filling the first structuring separating trenches with at least one insulator material,
m) filling the second structuring separating trenches with at least one conductive material,
n) forming at least one conductive bridge, using a conductive material, from one of the second structuring separating trenches which are filled with the conductive material, or the first linear conductive areas via the adjacent first structuring separating trenches which are filled with the insulator material, to the front electrode layer of an adjacent solar cell to electrically connect the solar cells in series.

61. A method for manufacturing a thin-film solar module, comprising:
a) providing a planar substrate layer,
b) applying at least one back electrode layer to the substrate layer,
c) applying at least one conductive barrier layer to at least one of the substrate layer and the back electrode layer,
d) applying at least one ohmic contact layer to the barrier layer,
e) applying one of a kesterite or a chalcopyrite semiconductor absorber layer to the contact layer,
f) applying at least one first buffer layer to the semiconductor absorber layer,
g) applying at least one second buffer layer to one of the first buffer layer or the semiconductor absorber layer,
h) applying at least one front electrode layer to one of the semiconductor absorber layer, the first buffer layer, or the second buffer layer,
i) performing at least one first structuring step by removing the layers applied to the substrate layer, along spaced-apart lines with the aid of a first laser treatment, to form first structuring separating trenches which separate adjacent solar cells,
j) performing at least one second structuring step which includes removing layers which extend from one of the contact layer, the back electrode layer, or the barrier layer, up to and including the front electrode layer, along spaced-apart lines, to form second structuring separating trenches which are adjacent to the first structuring separating trenches and which extend, at least in sections, essentially in parallel to the first structuring separating trenches,
k) filling the first structuring separating trenches with at least one insulator material,
l) filling a first volume area of the second structuring separating trenches, which extends from one of the contact layer, the back electrode layer, or the barrier layer, to the front electrode layer along the separating trench wall adjacent to the first structuring separating trench, with at least one conductive material, while leaving open a second volume area adjacent to the first volume are, the second volume are extending from the barrier layer to the front electrode layer along the separating trench wall which is not adjacent to the first structuring separating trench, and
m) forming at least one conductive bridge, using a conductive material, from the first volume areas of the second structuring separating trenches which are filled with conductive material, over adjacent first structuring separating trenches which are filled with the insulator material, to the front electrode layer of an adjacent solar cell to electrically connect the solar cells in series.

62. The method as recited in claim 60, wherein the contact layer contains at least one of molybdenum, tantalum, zirconium, cobalt, niobium, tungsten, metal selenide, metal sulfide, and metal sulfoselenide.

63. The method as recited in claim 60, wherein the semiconductor absorber layer includes one of a quaternary IB-IIIA-VIA chalcopyrite layer, a pentenary IB-IIIA-VIA chalcopyrite layer, or a kesterite layer.

64. The method as recited in claim 60, wherein metals which are present in the contact layer are at least partially converted into at least one of metal selenides, metal sulfides, and metal sulfoselenides by applying the one of the kesterite or chalcopyrite semiconductor absorber layer to the contact layer.

65. The method as recited in claim 60, wherein the step of applying the semiconductor absorber layer includes: depositing all metallic components of the semiconductor absorber layer on the contact layer to form a metal ply, and treating the metal ply with at least one of selenium compound and a sulfur compound.
